(19) United States
(12) Patent Application Publication
(10) Pub. No.: US 2025/0350000 A1
(43) Pub. Date: Nov. 13, 2025

(54) MODULAR FLEX CIRCUIT INTEGRATION FOR VARIED SERIES COUNT CONFIGURATIONS FOR A BATTERY

(71) Applicant: GM GLOBAL TECHNOLOGY OPERATIONS LLC, Detroit, MI (US)

(72) Inventors: Michael Victor Pyrtko, Ferndale, MI (US); Paul Campbell, Rochester, MI (US); Michael A. Smith, Clarkston, MI (US)

(73) Assignee: GM GLOBAL TECHNOLOGY OPERATIONS LLC, Detroit, MI (US)

(21) Appl. No.: 18/657,456

(22) Filed: May 7, 2024

(51) Int. Cl. H01M 50/569; G01R 31/396; H01M 10/48; H01M 50/528

(52) U.S. Cl. CPC H01M 50/569; G01R 31/396; H01M 10/48; H01M 50/528

(57) ABSTRACT

Disclosed is a method which may include providing a battery cell sensing application specific integrated circuit comprising at least a first channel and a second channel, a first connection line connected to the first channel and a second connection line connected to the second channel, a first weld pad connected to the first connection line, a second weld pad connected to the second connection line, and binding a first shunt to the first weld pad and the second weld pad.

### INTRODUCTION

The technical field generally relates battery, components thereof and methods of making the same.

Batteries have heretofore utilized the mechanical connector for connecting sense line assemblies together.

It is desirable to provide a design and method of manufacturing batteries without utilizing a mechanical connector for connecting sense line assemblies together. Furthermore, other desirable features and characteristics of the variations disclosed herein will become apparent from the subsequent detailed description and the appended claims, taken in conjunction with the accompanying drawings and the foregoing.

### SUMMARY

A number of variations may include a method including: providing a battery cell sensing application specific integrated circuit including at least a first channel and a second channel, a first connection line connected to the first channel, a second connection line connected to the second channel, a first weld pad connected to the first connection line and a second weld pad connected to the second connection line; and welding a first shunt to the first weld pad and the second weld pad.

A number of variations may include a method wherein the battery cell sensing application specific integrated circuit further includes a third channel and a fourth channel, a third connection line connected the third channel, a fourth connection line connected to the fourth channel, third weld pad connected to the third connection line, and fourth weld pad connected to the fourth connection line; and welding a second shunt to the third weld pad and fourth weld pad.

A number of variations may include a method further including a first extension including a first flexible circuit including a first sense line trace.

A number of variations may include a method further including connecting a first wire bond to the first sense line trace and to the first shunt.

A number of variations may include a method further including connecting a first wire bond to the first weld pad and the first connection line, and connecting a second wire bond to the second weld pad and the second connection line.

A number of variations may include a method wherein the battery cell sensing application specific integrated circuit including a third channel and a fourth channel, a third connection line connected to the third channel and a fourth connection line connected to the fourth channel, a third weld pad connected to the fourth connection line and a fourth weld pad connected to the fourth connection line; and welding a second shunt to the third weld pad and the fourth weld pad.

A number of variations may include a method further including a second extension including a second flexible circuit including a second sense line trace.

A number of variations may include a method further including connecting a second wire bond to the second sense line trace and to a second shunt.

A number of variations may include a method further including connecting a third wire bond to the third weld pad and the third connection line, and connecting a fourth wire bond to the fourth weld pad and the fourth connection line.

A number of variations may include a method wherein the battery cell sensing application specific integrated circuit further including at least a third channel, a third connection line connected to a third weld pad, a second sense line trace connected to a second cell or cell group; and further including welding the first shunt to the third weld pad.

A number of variations may include a method wherein the battery cell sensing application specific integrated circuit further including at least a fifth channel, a fifth connection line connected to a fifth weld pad; and further including welding the second shunt to the fifth weld pad.

A number of variations may include a method including: providing at least a first modular component, a second modular component, and a third modular component wherein each the first modular component, the second modular component, and the third modular component includes a battery cell sensing application specific integrated circuit including at least a first channel, a second channel, and a third channel, a first connection line connected to the first channel, a second connection line connected to the second channel, a third connection line connected to the third channel, a first weld pad connected to the first connection line, a second weld pad connected to the second connection line, a third weld pad connected to the third connection line, wherein both of the first modular component, the second modular component, and the third modular component each have a first circuit configuration; and changing the first circuit configuration of the first modular component including connecting a first shunt to at least the first weld pad and the second weld pad of the first modular component.

A number of variations may include a method further including changing the first circuit configuration of the second modular component including connecting the first shunt to the first weld pad, the second weld, and the third weld pad of the second modular component.

A number of variations may include a method including leaving the first circuit configuration of the third modular component unchanged.

A number of variations may include a method wherein the battery cell sensing application specific integrated circuit further includes a fourth channel, a fifth channel, and a sixth channel, a fourth connection line connected and the fourth channel and a fourth weld pad, a fifth connection line connected to the fifth channel and a fifth weld pad, and a sixth connection line connected to the sixth channel and to a sixth weld pad; and welding a second shunt to at least the fourth weld pad and fifth weld pad.

A number of variations may include a method further including a first extension including a first flexible circuit including a first sense line trace and a second sense line trace connected to a first cell or cell group.

A number of variations may include a method further including connecting a first wire bond to the first sense line trace and to the first shunt, and connecting a second wire bond to the second sense line trace and to the first shunt.

A number of variations may include a method further including a second extension including a second flexible circuit including a third sense line trace and a fourth sense line trace connected to a second cell or cell group.

A number of variations may include a method further including connecting a second wire bond to the third sense line trace and to the second shunt.

A number of variations may include a product including: a battery cell sensing application specific integrated circuit including at least a first channel and a second channel, a first connection line connected to the first channel and a second connection line connected to the second channel, a first weld pad connected to the first connection line and a second weld pad connected to the second connection line; and a first shunt welded to the first weld pad and the second weld pad.

### BRIEF DESCRIPTION OF THE DRAWINGS

A number of variations will hereinafter be described in conjunction with the following drawing figures, wherein like numerals denote like elements, and wherein:

FIG. 1 illustrates a product which may include a portion of a battery management system according to a number of variations;

FIG. 2 illustrates a product which may include a sense line assembly including a first shunt and a second shunt used to reconfigure a modular sense line assembly according to a number of variations;

FIG. 3 illustrates a product which may include a sense line assembly including a first shunt and a second shunt used to reconfigure a modular sense line assembly according to a number of variations;

FIG. 4 illustrates a product which may include a modular central integrated circuit board and sense line assembly module and a pair of extensions, wherein each extension includes a shunt reconfiguring the modular central integrated circuit board and sense line assembly according to a number of variations;

FIG. 5 illustrates a product which may include a central integrated circuit bus and sense line assembly module and a pair of extensions, wherein each extension includes a shunt reconfiguring a modular central integrated circuit board and sense line assembly according to a number of variations; and

FIG. 6 is a side view illustrating a product which may include a first flexible circuit and a first wire bond connecting the first flexible circuit and a first shunt, and a second flexible circuit and a second wire bond connecting the second flexible circuit and a weld pad according to a number of variations.

### DETAILED DESCRIPTION

The following detailed description is merely illustrative in nature and is not intended to limit the application and uses. Furthermore, there is no intention to be bound by any expressed or implied theory presented in the preceding introduction, brief description of the drawings, and summary or the following detailed description.

A plurality of sense lines, which are low current traces between cells and a battery management system, may be utilized to manage a battery cell or group of cells in a battery. When one or more cells are at a peak voltage, and other cells are lower, a relay may close to discharge the peak voltage cell (or group of cells) through a balancing resistor. This will reduce the voltage to match the next highest voltage cell.

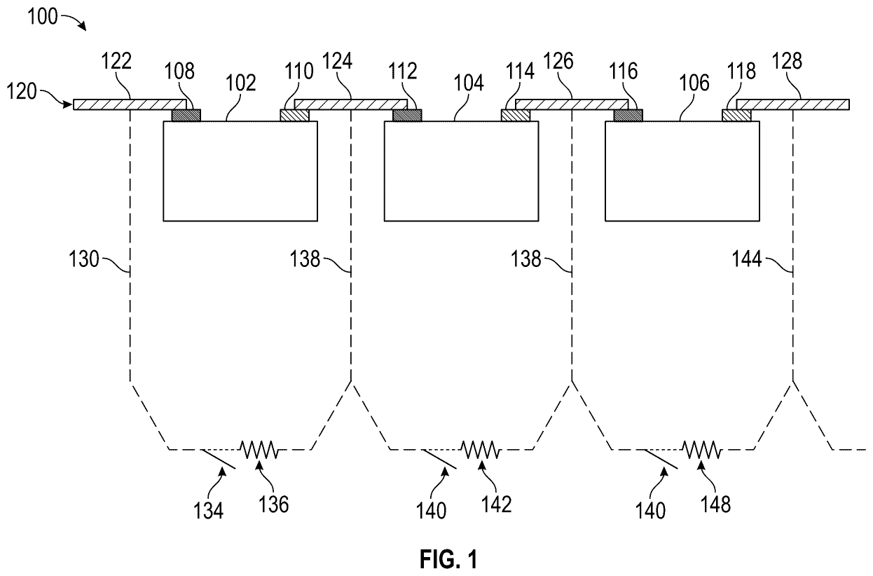

A number of variations are illustrated in FIG. 1, which may include a product 100 which may be a portion of a battery management system and may include a plurality of battery cells or cell groups including a first cell or cell group 102, a second cell or cell group 104, third cell or cell group 106 and so on. The first cell or cell group 102 may include a first terminal 108 which may be a positive terminal, and a second terminal 110 which may be a negative terminal. Similarly, the second cell or cell group 104 may include a first terminal 112 which may be a positive terminal and a second terminal 114 which may be a negative terminal, and the or cell group 106 may include a first terminal 116 which may be a positive terminal and a second terminal 118 which may be a negative terminal. A busbar 121 may include a plurality of portions connected to each cell or cell group, respectively. In a number of variations, a first portion 122 of the busbar 121 may be connected to the first terminal 108 of the first cell or cell group 102. A second portion 124 of the busbar 121 may be connected to the second terminal 110 of the first cell or cell group 102 and to the first terminal 112 of the second cell or cell group 104. Similarly, third portion 126 of the busbar 121 may be connected to the second terminal 114 of the second cell or group and to the first terminal 116 of the third cell or cell group 106. The busbar 121 may include a fourth portion 128 that may be connected to the second terminal 118 of the third cell or cell group 106.

A first sense line 130 may be connected to the first portion 122 of the busbar 121 and a second sense line 138 may be connected to the second portion 124 of the busbar 121. The first sense line 130 and the second sense line 138 may be selectively connected together by a first relay 134 and a first balancing resistor 136 positioned to operate when the first relay 134 closes. A third sense line 139 may be connected to the third portion 126 of the busbar 121. The third sense line 139 and the second sense line 138 may be selectively connected together by a second relay 140 and a second balancing resistor 142 positioned to operate when the second relay 140 closes. A fourth sense line 144 may be connected to the to the fourth portion 128 of the busbar 121. The fourth sense line 144 and the third sense line 139 may be selectively connected together by a third relay 146 and a third balancing resistor 148 positioned to operate when the third relay 146 closes.

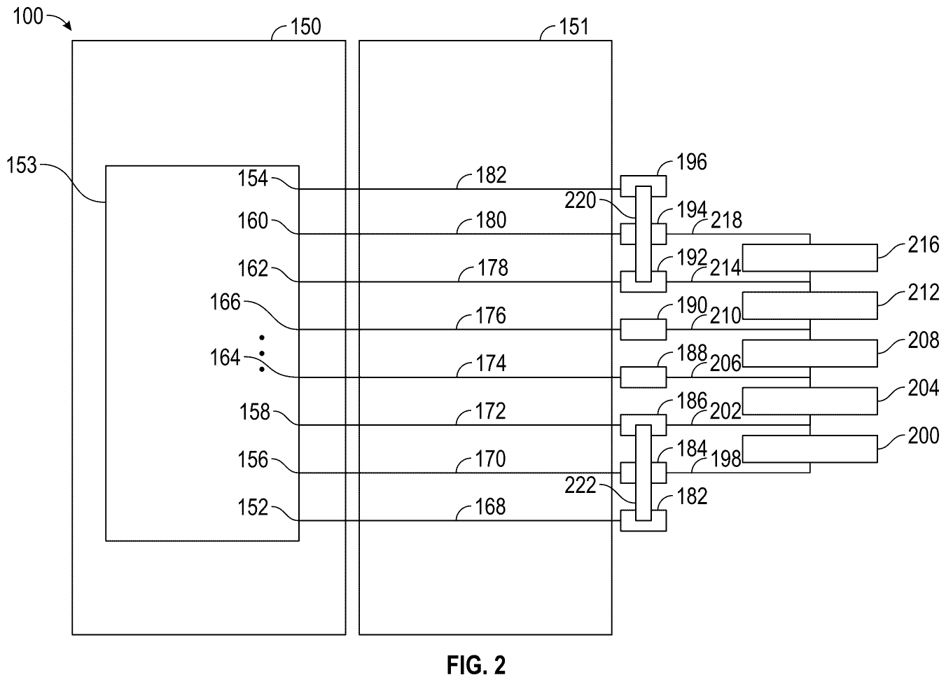

FIG. 2 illustrates a number of variations, which may include a product 100 which may include a battery management system cell sensing device 150 which may include a cell sensing application specific integrated circuit (ASIC) 153. The cell sensing ASIC 153 may include a plurality of channels for sense lines to connect to including, for example an ASIC ground channel 152 and an ASIC power channel 154. A plurality of other channels may be provided, for example, channel 0 illustrated by reference 156, channel 1 illustrated by reference 158, channel N illustrated by reference 160, channel N-1 illustrated by reference 162, and a plurality of other channels, for example, a first channel 164 and a second channel 166.

A sense line interconnection device 151 may be provided and may include a plurality of interconnection lines or pathways. A first connection line 168 may be connected to the ASIC ground channel 152 and to first weld pad 182. A second connection line 170 may be connected to channel 0 indicated by reference 156 and to a second weld pad 184. A third connection line 172 may be connected to channel 1 indicated by reference 158 and to third weld pad 186. A fourth connection line 174 may be connected to the first channel 164 and to a fourth weld pad 188. A fifth connection line 176 may be connected to the second channel 166 and to a fifth weld pad 190. A sixth connection line 178 may be connected to channel N-1 162 and to a sixth weld pad 192. A seventh connection line 180 may be connected to channel N 160 and to a seventh weld pad 194. And an eighth connection line 181 may be connected to the ASIC power channel and to an eighth weld pad 196.

In a similar manner as illustrated in FIG. 1, a plurality sense line traces may be connected to terminals of a cell or group of cells. For example, a first sense line trace 198 may be directly or indirectly connected to the second weld pad 184 and a first cell or cell group 200. A second sense line trace 202 may be directly or indirectly connected to the third weld pad 186 and to the first cell or cell group 200 and to a second cell or cell group 204. A third sense line trace 206 may be directly or indirectly connected to the fourth weld pad 188 and to the second cell or cell group 204 and to a third cell or cell group 208. A fourth sense line trace 210 may be directly or indirectly connected to the fifth weld pad 190 and to the third cell or cell group 208 and to a fourth cell or cell group 212. A fifth sense line trace 214 may be directly or indirectly connected to the sixth weld pad 192 and to the fourth cell or cell group 212 and to a fifth cell or cell group 216. A sixth sense line trace 28 may be directly or indirectly connected to the seventh weld pad 194 and to the fifth cell or cell group 216. A first shunt 220 may be connected to the first weld pad 182, the second weld pad 184, and the third weld pad 186. Adding the first shunt 220 result in the first cell or cell group being unpopulated and is ignored in cell balancing by the battery management system. A second shunt 222 may be connected to the eighth weld pad 196, the seventh weld pad 194, and the sixth weld pad 192. Adding the second shunt 222 results in the fifth cell or cell group being unpopulated and is ignored in cell balancing by the battery management system. A relay and balancing resistor may be provided and selectively connected to two sense lines, for example as illustrated in FIG. 1, for each cell of cell group.

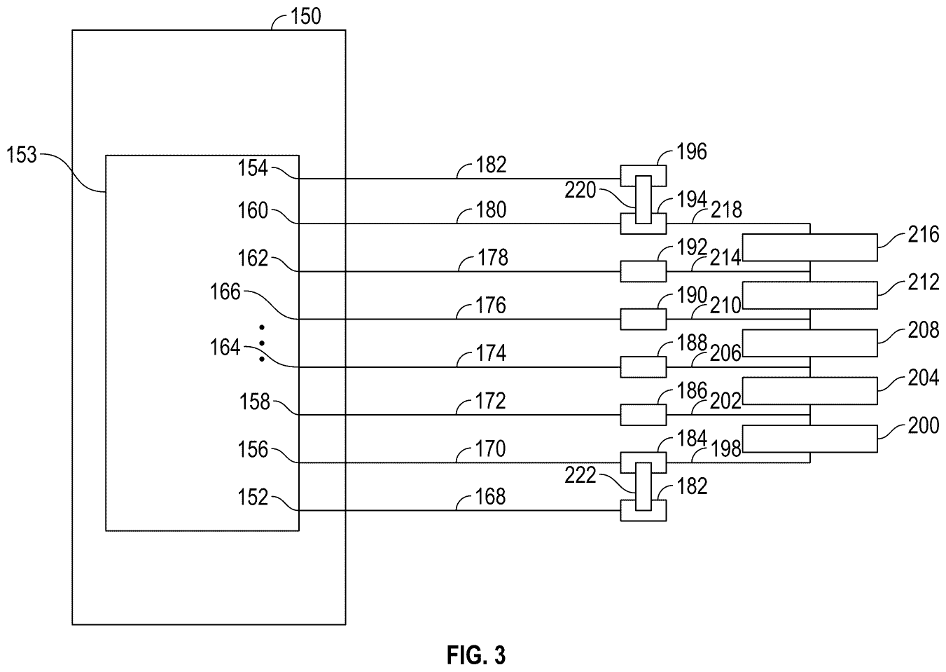

A number of variations are illustrated in FIG. 3, which may be similarly constructed as illustrated in FIG. 2 except that a sense line interconnect device is not provided, and the first shunt 220 may be connected to the first weld pad 182 and the second weld pad 184 to short together the ASIC power channel 154 and the channel 0 152. The second shunt 222 may be connected to the eighth weld pad 196 and the seventh weld pad 194 to short together the ASIC power channel 154 and the channel N 160, and. As will be appreciated from the variations illustrated in FIGS. 1-2 at least one shunt may be used to short at least two weld pads together and/or to unpopulated at least one cell or cell group.

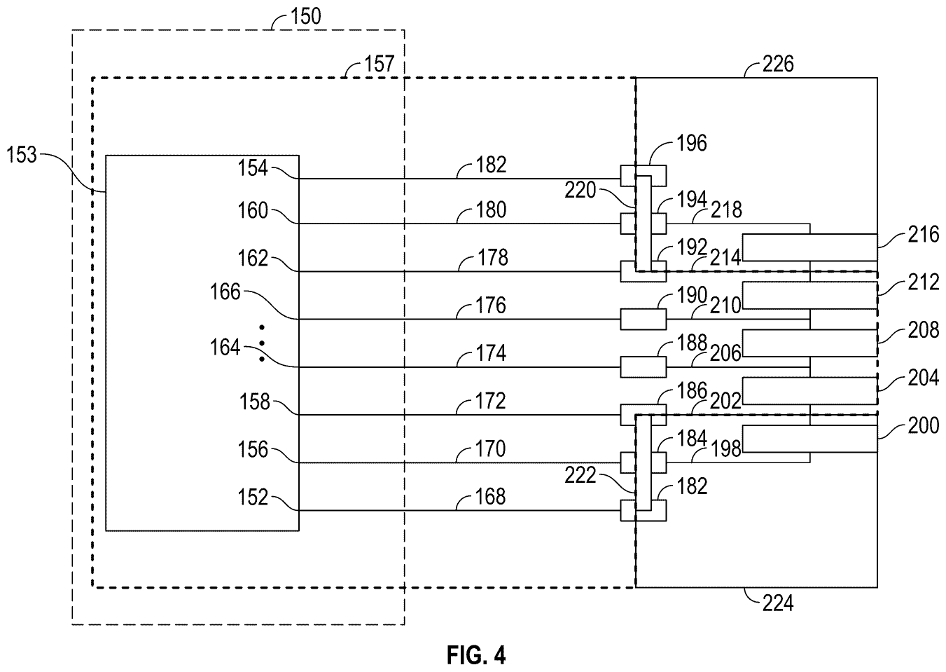

A number of variations are illustrated in FIG. 4, which may a first modular component which may include a central integrated circuit board and sense line assembly 157 which may include the battery management system cell sensing device 150, the cell sensing ASIC 153, a plurality of connection lines, a plurality of weld pads, and/or web plurality of sense lines. At least one extension, for example, a first extension 224 and/or a second extension 226 may be provided. The first extension 224 and/or the second extension 226 may be positioned in the same plane as the central integrated circuit board and sense line assembly 157, or at least a portion of the first extension 224 and/or the second extension 226 may overlie the central integrated circuit board and sense line assembly 157. The first extension 224 and/or the second extension 226 may include at least one sense line, or the at least one shunt or at least one shunt may be provided as a separate piece.

The cell sensing ASIC 153 may include a plurality of channels for sense lines to connect to including, for example an ASIC ground channel 152 and an ASIC power channel 154. A plurality of other channels may be provided, for example, channel 0 illustrated by reference 156, channel 1 illustrated by reference 158, channel N illustrated by reference 160, channel N-1 illustrated by reference 162, and a plurality of other channels, for example, a first channel 164 and a second channel 166.

A first connection line 168 may be connected to the ASIC ground channel 152 and to first weld pad 182. A second connection line 170 may be connected to channel 0 indicated by reference 156 and to a second weld pad 184. A third connection line 172 may be connected to channel 1 indicated by reference 158 and to third weld pad 186. A fourth connection line 174 may be connected to the first channel 164 into fourth weld pad 188. A fifth connection line 176 may be connected to the second channel 166 and to a fifth weld pad 190. A sixth connection line 178 may be connected to channel N-1 162 and to a sixth weld pad 192. A seventh connection line 180 may be connected to channel N 160 and to a seventh weld pad 194. And an eighth connection line 181 may be connected to the ASIC power channel and to an eighth weld pad 196.

In a similar manner as illustrated in FIG. 1, a plurality sense lines may be connected to terminals of a cell or group of cells. The first extension 224 may include a first sense line trace 198 which may be directly or indirectly connected to the second weld pad 184 or the first shunt 220, and a first cell or cell group 200. A second sense line trace 202 may be directly or indirectly connected to the third weld pad 186 and to the first cell or cell group 200 and to a second cell or cell group 204. A third sense line trace 206 may be directly or indirectly connected to the fourth weld pad 188 and to the second cell or cell group 204 and to a third cell or cell group 208. A fourth sense line trace 210 may be directly or indirectly connected to the fifth weld pad 190 and to the third cell or cell group 208 and to a fourth cell or cell group 212. A fifth sense line trace 214 may be directly or indirectly connected to the sixth weld pad 192 and to the fourth cell or cell group 212 and to a fifth cell or cell group 216. The second extension 226 may include a sixth connection line trace 218 which may be directly or indirectly connected to the seventh weld pad 194 or to the second shunt 222, and to the fifth cell or cell group 216. A first shunt 220 may be connected to the first weld pad 182, the second weld pad 184, and the third weld pad 186. Adding the first shunt 220 result in the first cell or cell group being unpopulated and is ignored in cell balancing by the battery management system. A second shunt 222 may be connected to the eighth weld pad 196, the seventh weld pad 194, and the sixth weld pad 192. Adding the second shunt 222 results in the fifth cell or cell group being unpopulated and is ignored in cell balancing by the battery management system. A relay and balancing resistor may be provided and selectively connected to two sense lines, for example as illustrated in FIG. 1, for each cell of cell group.

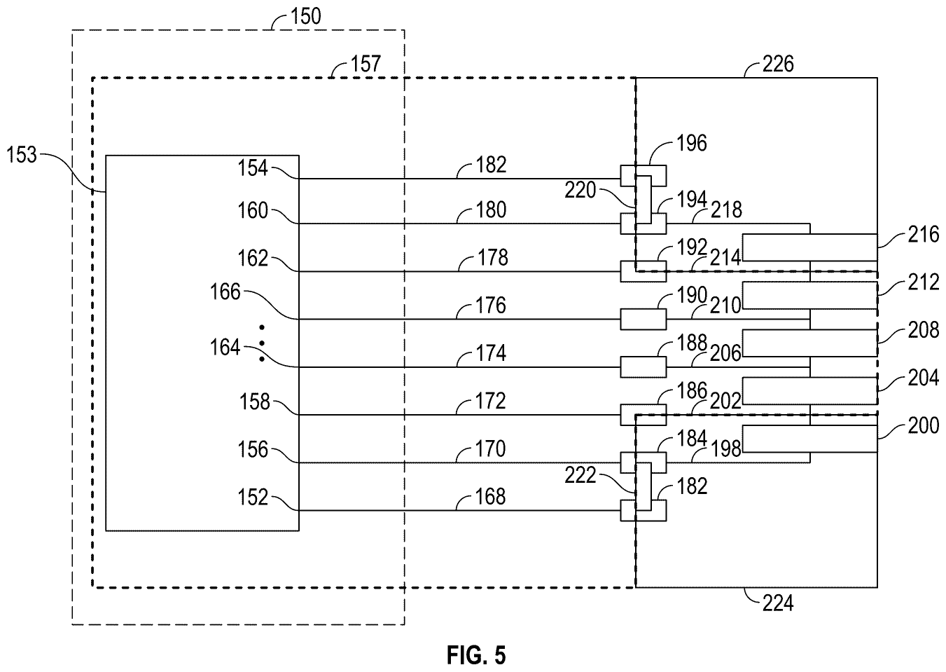

A number of variations are illustrated in FIG. 5, which may be similarly constructed as illustrated in FIG. 4 except that the second shunt 222 may be connected to the eighth weld pad 196 and the seventh weld pad 194 to short together the ASIC power channel 154 and the channel N 160, and the first shunt 220 may be connected to the first weld pad 182 and the second weld pad 184 to short together the ASIC power channel 154 and the channel 0 152. As will be appreciated from the variations illustrated in FIGS. 4-5 at least one shunt may be used to short at least two weld pads together and/or to unpopulated at least one cell or cell group.

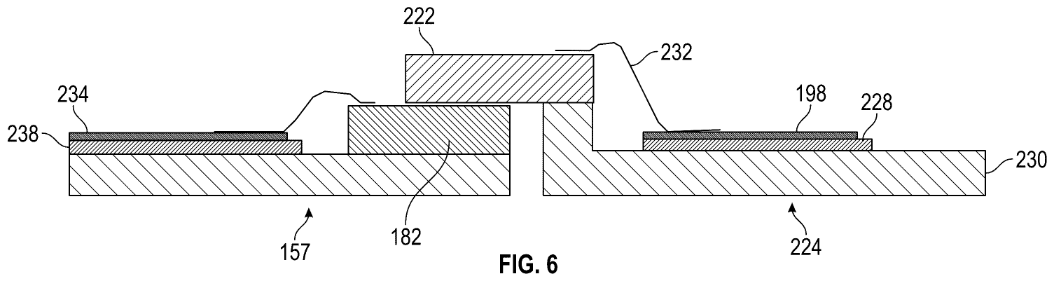

A number of variations are illustrated in FIG. 6, which may include a product 100 which may include a first extension 224 which may include a first sense line trace 198 connected to a first shunt 220 by a first wire bond 232. The first sense line trace 198 may be carried or enclosed in a first polymeric material 228, for example, a polyamide. The first sense line trace 198 and the first polymeric material 228 may form a first flexible circuit 238. The first polymeric material 228 and the first sense line trace 198 may be supported by a first substrate 230, which may be a nonconductive substrate such as a fiberglass board. A first modular component may be a central integrated circuit board and sense line assembly 157 may include a first connection line 168 which may be carried by or enclosed by a second polymeric material 236. The first connection line 168 may be connected to a first weld pad 182 by a second wire bond 234. A first shunt 220 may be welded to a first weld pad 182 and a first connection line 168 connected to the first weld pad 182 by a second wire bond 234. The first weld pad 182 may be a part of the central integrated circuit board and sense line assembly 157 may be a separate piece.

Clause 1. A method comprising: providing a battery cell sensing application specific integrated circuit comprising at least a first channel and a second channel, a first connection line connected to the first channel, a second connection line connected to the second channel, a first weld pad connected to the first connection line and a second weld pad connected to the second connection line; and welding a first shunt to the first weld pad and the second weld pad.

Clause 2. The method as set forth in clause 1 wherein the battery cell sensing application specific integrated circuit further comprises a third channel and a fourth channel, a third connection line connected the third channel, the fourth connection line connected to fourth channel, third weld pad connected to the third connection line, and fourth weld pad connected to the fourth connection line; and welding a second shunt to the third weld pad and fourth weld pad.

Clause 3. A method as set forth in clause 1 further comprising a first extension comprising a first flexible circuit including a first sense line trace.

Clause 4. A method as set forth in clause 3 further comprising connecting a first wire bond to the first sense line trace and to the first shunt.

Clause 5. A method as set forth in clause 1 further comprising connecting a first wire bond to the first weld pad and the first connection line, and connecting a second wire bond to the second weld pad and the second connection line.

Clause 6. A method as set forth in clause 3 wherein the battery cell sensing application specific integrated circuit comprising a third channel and a fourth channel, a third connection line connected to the third channel and a fourth connection line connected to the fourth channel, a third weld pad connected to the fourth connection line and a fourth weld pad connected to the fourth connection line; and welding a second shunt to the third weld pad and the fourth weld pad.

Clause 7. A method as set forth in clause 6 further comprising a second extension comprising a second flexible circuit including a second sense line trace.

Clause 8. A method as set forth in clause 7 further comprising connecting a second wire bond to the second sense line trace and to a second shunt.

Clause 9. A method as set forth in clause 8 further comprising connecting a third wire bond to the third weld pad and the third connection line, and connecting a fourth wire bond to the fourth weld pad and the fourth connection line.

Clause 10. A method as set forth in clause 1 wherein the battery cell sensing application specific integrated circuit further comprising at least a third channel, a third connection line connected to a third weld pad, a second sense line trace connected to a second cell or cell group; and further comprising welding the first shunt to the third weld pad.

Clause 11. A method as set forth in clause 6 wherein the battery cell sensing application specific integrated circuit further comprising at least a fifth channel, a fifth connection line connected to a fifth weld pad; and further comprising welding the second shunt to the fifth weld pad.

Clause 12. A method comprising: providing at least a first modular component, a second modular component, and a third modular component wherein each the first modular component, the second modular component, and the third modular component comprises a battery cell sensing application specific integrated circuit comprising at least a first channel, a second channel, and a third channel, a first connection line connected to the first channel, a second connection line connected to the second channel, a third connection line connected to the third channel, a first weld pad connected to the first connection line, a second weld pad connected to the second connection line, a third weld pad connected to the third connection line, wherein both of the first modular component, the second modular component, and the third modular component each have a first circuit configuration; and changing the first circuit configuration of the first modular component comprising connecting a first shunt to at least the first weld pad and the second weld pad of the first modular component.

Clause 13. A method as set forth in clause 12 further comprising changing the first circuit configuration of the second modular component comprising connecting the first shunt to the first weld pad, the second weld, and the third weld pad of the second modular component.

Clause 14. A method as set forth in clause 12 comprising leaving the first circuit configuration of the third modular component unchanged.

Clause 15. The method as set forth in clause 11 wherein the battery cell sensing application specific integrated circuit further comprises a fourth channel, a fifth channel, and a sixth channel, a fourth connection line connected and the fourth channel and a fourth weld pad, a fifth connection line connected to the fifth channel and a fifth weld pad, and a sixth connection line connected to the sixth channel and to a sixth weld pad; and welding a second shunt to at least the fourth weld pad and fifth weld pad.

Clause 16. A method as set forth in clause 15 further comprising a first extension comprising a first flexible circuit including a first sense line trace and a second sense line trace connected to a first cell or cell group.

Clause 17. A method as set forth in clause 16 further comprising connecting a first wire bond to the first sense line trace and to the first shunt, and connecting a second wire bond to the second sense line trace and to the first shunt.

Clause 18. A method as set forth in clause 16 further comprising a second extension comprising a second flexible circuit including a third sense line trace and a fourth sense line trace connected to a second cell or cell group.

Clause 19. A method as set forth in clause 18 further comprising connecting a second wire bond to the third sense line trace and to the second shunt.

Clause 20. A product comprising: a battery cell sensing application specific integrated circuit comprising at least a first channel and a second channel, a first connection line connected to the first channel and a second connection line connected to the second channel, a first weld pad connected to the first connection line and a second weld pad connected to the second connection line; and a first shunt welded to the first weld pad and the second weld pad.

At least one variation has been presented in the foregoing detailed description, it should be appreciated that a vast number of variations exist. It should also be appreciated that the variation or variations are only examples, and are not intended to limit the scope, applicability, or configuration of the disclosure in any way. Rather, the foregoing detailed description will provide those skilled in the art with a convenient road map for implementing the illustrative variation or variations. It should be understood that various changes can be made in the function and arrangement of elements without departing from the scope of the disclosure as set forth in the appended claims and the legal equivalents thereof.

What is claimed is:

1. A method comprising:
providing a battery cell sensing application specific integrated circuit comprising at least a first channel and a second channel, a first connection line connected to the first channel, a second connection line connected to the second channel, a first weld pad connected to the first connection line and a second weld pad connected to the second connection line; and
welding a first shunt to the first weld pad and the second weld pad.

2. The method as set forth in claim 1 wherein the battery cell sensing application specific integrated circuit further comprises a third channel and a fourth channel, a third connection line connected the third channel, a fourth connection line connected to the fourth channel, third weld pad connected to the third connection line, and fourth weld pad connected to the fourth connection line; and
welding a second shunt to the third weld pad and fourth weld pad.

3. The method as set forth in claim 1 further comprising a first extension comprising a first flexible circuit including a first sense line trace.

4. The method as set forth in claim 3 further comprising connecting a first wire bond to the first sense line trace and to the first shunt.

5. The method as set forth in claim 1 further comprising connecting a first wire bond to the first weld pad and the first connection line, and connecting a second wire bond to the second weld pad and the second connection line.

6. The method as set forth in claim 3 wherein the battery cell sensing application specific integrated circuit comprising a third channel and a fourth channel, a third connection line connected to the third channel and a fourth connection line connected to the fourth channel, a third weld pad connected to the fourth connection line and a fourth weld pad connected to the fourth connection line; and
welding a second shunt to the third weld pad and the fourth weld pad.

7. The method as set forth in claim 6 further comprising a second extension comprising a second flexible circuit including a second sense line trace.

8. The method as set forth in claim 7 further comprising connecting a second wire bond to the second sense line trace and to a second shunt.

9. The method as set forth in claim 8 further comprising connecting a third wire bond to the third weld pad and the third connection line, and connecting a fourth wire bond to the fourth weld pad and the fourth connection line.

10. The method as set forth in claim 1 wherein the battery cell sensing application specific integrated circuit further comprising at least a third channel, a third connection line connected to a third weld pad, a second sense line trace connected to a second cell or cell group; and
further comprising welding the first shunt to the third weld pad.

11. The method as set forth in claim 6 wherein the battery cell sensing application specific integrated circuit further comprising at least a fifth channel, a fifth connection line connected to a fifth weld pad; and
further comprising welding the second shunt to the fifth weld pad.

12. A method comprising:
providing at least a first modular component, a second modular component, and a third modular component wherein each the first modular component, the second modular component, and the third modular component comprises a battery cell sensing application specific integrated circuit comprising at least a first channel, a second channel, and a third channel, a first connection line connected to the first channel, a second connection line connected to the second channel, a third connection line connected to the third channel, a first weld pad connected to the first connection line, a second weld pad connected to the second connection line, a third weld pad connected to the third connection line, wherein both of the first modular component, the second modular component, and the third modular component each have a first circuit configuration; and
changing the first circuit configuration of the first modular component comprising connecting a first shunt to at least the first weld pad and the second weld pad of the first modular component.

13. The method as set forth in claim 12 further comprising changing the first circuit configuration of the second modular component comprising connecting the first shunt to the first weld pad, the second weld, and the third weld pad of the second modular component.

14. The method as set forth in claim 12 comprising leaving the first circuit configuration of the third modular component unchanged.

15. The method as set forth in claim 12 wherein the battery cell sensing application specific integrated circuit further comprises a fourth channel, a fifth channel, and a sixth channel, a fourth connection line connected and the fourth channel and a fourth weld pad, a fifth connection line connected to the fifth channel and a fifth weld pad, and a sixth connection line connected to the sixth channel and to a sixth weld pad; and
welding a second shunt to at least the fourth weld pad and fifth weld pad.

16. The method as set forth in claim 15 further comprising a first extension comprising a first flexible circuit including a first sense line trace and a second sense line trace connected to a first cell or cell group.

17. The method as set forth in claim 16 further comprising connecting a first wire bond to the first sense line trace and to the first shunt, and connecting a second wire bond to the second sense line trace and to the first shunt.

18. The method as set forth in claim 16 further comprising a second extension comprising a second flexible circuit including a third sense line trace and a fourth sense line trace connected to a second cell or cell group.

19. The method as set forth in claim 18 further comprising connecting a second wire bond to the third sense line trace and to the second shunt.

20. A product comprising:
a battery cell sensing application specific integrated circuit comprising at least a first channel and a second channel, a first connection line connected to the first channel and a second connection line connected to the second channel, a first weld pad connected to the first connection line and a second weld pad connected to the second connection line; and
a first shunt welded to the first weld pad and the second weld pad.
